(19) United States
(12) Patent Application Publication
(10) Pub. No.: US 2017/0260634 A1
(43) Pub. Date: Sep. 14, 2017

(54) Enhanced Exothermic Reaction (EER) Reactor

(71) Applicant: John Timothy Sullivan, Marriottsville, MD (US)

(72) Inventor: John Timothy Sullivan, Marriottsville, MD (US)

(21) Appl. No.: 15/417,812

(22) Filed: Jan. 27, 2017

Related U.S. Application Data
(60) Provisional application No. 62/288,885, filed on Jan. 29, 2016.

(51) Int. Cl. C25B 11/04; H01J 37/32; C25B 15/08; C25B 9/04; C25B 1/00; C25B 11/02

(52) U.S. Cl. CPC C25B 11/0426; C25B 1/00; C25B 11/02; C25B 15/08; C25B 9/04; H01J 37/3222; H01J 2237/33

(57) ABSTRACT

A method and apparatus for carrying out highly efficient switching inductive magnetic Enhanced Exothermic Reactions (EERs) on the surface of electrodes with a conductive electrically heated lithium-polymer electrolyte with switching magnetic fields while under hydrogen loading pressures to produce a second exothermal electrode surface and/or plasma heat reaction to heat a fluid, gas, or heat thermoelectric modules to produce electricity and store energy, while producing a cross-linked carbon graphene by-product at elevated temperatures using an auger to pump and transport the electrolyte fuel in a continuous or intermittent process or a onetime use. The device can self-start from an internal stored charge to electrically start a heated reaction.

This application claims the benefit of U.S. Provisional Patent Appl. Ser. No. 62/288,885, filed Jan. 29, 2016, and incorporated by reference herein.

### BACKGROUND OF THE INVENTION

1. Field of the Invention

The present invention relates to enhanced exothermic reactions (EERs), and more particularly to a method and apparatus for carrying out pressurized hydrogen loading of nickel (Ni), titanium (Ti), beryllium, palladium, ruthenium, copper, Iron (Fe) and other metals to produce an EER using a lithium based polymer.

2. Description of Related Art

Many alternative energy sources have already been explored and operatively tested even on an industrial scale, including biomasses, solar energy used both for heating and photovoltaic electric generation purposes, Aeolian energy, fuel materials of a vegetable or agricultural nature, geothermal and sea wave energy, and so on.

Other possible alternatives to natural oil are plasma fusion energy, which requires temperatures in the 100,000° C. range that vaporize metals on contact if the magnetic fields that suspend the plasma are lost, and nuclear fission, which suffers from yet unresolved problems such as safety and waste material processing problems since, as is well known, radioactive waste materials remain dangerously active for thousands or millions of years, with consequent great risks for persons living near radioactive waste disposal places.

The above drawbacks are also true for a lithium-nickel based EER unit such as described in published patent application US20110005506 to Andrea Rossi (the Rossi unit), which uses an external, inefficient electrical heater to heat the lithium and nickel metal powders to cause an exothermal reaction in a static reactor chamber, and which requires the reactor to be turned off to replace spent fuels. The startup electrical heat in the Rossi unit heats through an insulated ceramic tube and then into the center of a tube of the cell where a lot of the heat energy is wasted into ambient surrounding air. The present invention differs from the Rossi unit in a number of ways: First, in contrast to the Rossi unit, embodiments of the present invention use internal heat so that the energy is localized within the system with higher efficiencies. Second, embodiments of the present invention use an auger that replaces spent fuels with new fuels without turning the reactor off. The auger can have an enteral heater with slip-rings to supply power to the rotating auger, or the outside housing can rotate, keeping the heated auger stationary to move any combination or single element of Li, Ni, Fe, Ti, Mn, Fe, Co, Ru, Rh, Pd, Ag, Ta, W, Re, Ir, Pt, Au, Bh, Cn and a polymer out of the heater zone with a controlled temperature feedback loop that measures the reaction temperature, such that as the reaction drops below a software programmed desired temperature limit, the spent fuels are transported out and new fuels are transported in to replace the spent fuels over time using a motor controller. Embodiments of the present invention can also use the lithium based conductive polymer as the internal heater to extract hydrogen more efficiently than external chromium wire style heaters or inductive water cooled heaters. Still further, embodiments of the present invention use switching multi-directional currents and magnetic fields, which the Rossi unit does not. Also, unlike the Rossi unit, the present invention produces graphene as a waste by-product that is more valuable than the raw ingredients used, so that the graphene provides a second revenue stream in addition to the revenue from the electrical customer who is paying not only for the electricity but also for the cost of producing the graphene. Finally, the EER apparatus of the present invention can store a charge as a battery, which the Rossi unit does not.

Another EER system, disclosed in U.S. Patent Publication No. 2014/0332087 (the Godes reactor), uses nickel materials and pressurizes hydrogen to create an exothermic reacting using electrical power supply pulses and other external sources such as ultrasonic waves. Again, however, the Godes reactor is a start stop reactor unlike that of the present invention, which uses an auger and motor control feedback loop to replace spent fuels so that the unit reactor can run continuously while replacing all fuels and metals. Also, the Godes reactor uses gas fuels but has no provision for replacing the nickel without taking the reactor off line, and uses an external heater with electrical supply pulses. In contrast, the present invention makes use of pulsed power provided by a switching magnetic field within coiled heater electrodes, as described in prior patents of the inventor, the magnetic field switching as the current changes directions with a reversing floating ground and floating positive current paths. As applied to the present invention, the counter-electromotive forces that are collapsing from stored inductive, capacitive loads between the two electrodes and resistive electrolyte reversing causes osculation within the nickel lattice to pack the hydrogen and assist in a ferromagnetic spin and femtometer-level EER that occur in isotopes with low lying excited states. The present invention may utilize a random face-centered cubic iron-nickel alloy in which non-collinear spin alignments are allowed for, i.e., spins that may be canted with respect to the average magnetization direction, so that the alloy can be altered by altering the spin vectors in response to switching of the magnetic field, and so that the magnetic structure is characterized, even at zero temperature, by a continuous transition from the ferromagnetic state at a high state at high volumes to a disordered non-collinear configuration at low volumes. The switching magnets field can be adjusted by the function generator, material resistance, and a simple software solution to track and maintain the sweet spot in the harmonic osculations within the lattice, measured by heat and or radio frequency osculations. Finally, another difference is that the Godes reactor does not make a usable carbon waste product such as graphene extruded products, and in which nitrogen can be added as a cross linker bond between carbon bonds to replace oxygen.

### SUMMARY OF THE INVENTION

The invention provides a method and apparatus for producing EER using a lithium based polymer to achieve pressurized hydrogen loading by carrying out highly efficient switching inductive magnetic EER on the surface of electrodes, using a conductive electrically heated lithium-polymer electrolyte and switching magnetic fields while under hydrogen loading pressures to produce a second exothermal electrode surface and/or plasma heat reaction that heats a fluid, gas, or thermoelectric module(s) to produce electricity and store energy.

In one preferred embodiment of the invention, the polymer may be polyethylene, which contains two carbon atoms and four hydrogen atoms for the hydrogen fuel source. A conductive material such as graphene, graphite, carbon nano tubes and/or powder transition gives the polymer electrolyte an electrical resistance to carry an electrical charge between anode and cathodes and cause reactive EER on the electrodes or powders within the polymer matrix. The carbon material in the poly matrix is turned into graphene at elevated exothermic lattice reaction temperatures. Additional methane with or without nitrogen can assist in the graphene cross-linking under pressure and elevated temperatures with or without a magnetic field, as the hydrogen is absorbed into the lattice of the transition cathode or anode Ni or Ti with a small amount of Fe to create an exothermal heat reaction that releases more heat energy output than the electrical input power required to start the reaction the reaction in a cell. The input power is supplied from an outside electrical power heat source or other sources such as solar or flame. The greater Coefficient of Performance (over CoP), i.e., the amount that the output exothermal lattice reaction is greater than the starting input starting power, results in additional heat energy that may be converted into electricity and fed back into the cell to keep the reaction going with a feedback loop. The invention can use the harmonic feedback loop from the plasma arc or a pickup coil on the electrical ground path and convert the RF osculation's into an input electrical wave form to improve efficiencies by keeping the surface metal lattice that is in osculation out of equilibrium with its own natural RF osculation's. The waste by-product is crossed-linked graphene and the high temperatures of the exothermal reactions allow for a low cost of production due to the cost recovered in selling the over CoP electrical power to the grid.

The above-described configuration produces a phase 1 heat reaction within the lithium (Li) conductive polymer (Pe) in response to generation of electrically charged switching pulsing magnetic switching fields between charged electrodes that causes charged hydrogen ions to leave the polymer under heat, pressure and the electrical current path and load into the surface of the metal conductive electrodes. The pressurized loading creates a secondary phase 2 exothermal reaction on the surface of a metal plated foam carbon graphite electrode or other materials and configurations to produce a second phase 2 exothermal high heat reaction under heat, pressure and electrical loading. The secondary phase 2 exothermal reaction creates a higher heat source than the phase 1 heat reaction to heat a fluid or gas, or produce waste heat, Rankin style closed loop electricity, or a plasma between the electrodes that magnetically induces an Aneutronic fusion coil to convert the switching magnetic fields between electrodes directly into electricity.

The energy sources may be alternative to fossil sources, to prevent atmospheric carbon dioxide contents from being unnecessarily increased while producing a phase 3 useful cross-linked graphene waste by-product that is formed under pressure and heat, effectively using the switching electro-magnetic fields to turn a Lithium polymer that contains carbon and hydrogen into a graphene by-product without carbon dioxide emissions. The graphene by-product can be used to build useful products such a conductive wire and other products, and at the same time produce electricity to perform work. The released hydrogen gas is absorbed into the electrode to produce an exothermal reaction while the carbon is turned into graphene at temperatures in the 500 C to 1,000 C range. The production of both graphene and electricity can be carried out continuously or intermittently, using an auger or other means to remove the graphene while resupplying the conductive carbon and hydrogen. Additional hydrogen can also be supplied to the reaction externally to increase the temperature reaction. The system is argon flushed to remove all oxygen during the Phase 1, 2, and 3 closed process.

The polyethylene fuel source can be made from fossil fuels, plants and other methods. The carbon based materials are added to the polymer to make it electrically conductive, which will cause the fluid polymer to cross-link to the resistive electrically charged current-carrying carbon to form a new joined extruded cross-linked graphene while under high heat and electrical charge and while under the switching magnetic fields. The graphene can be extruded on the fly as the hydrogen.

In a variation of the above-described embodiment of the invention, the polarity of the heater cathodes and anodes remain constant while the current within the cathode switches back and forth from one end of the electrode to the other in a see saw motion that chases the floating ground path, both positive and negative connections being out of phase to create a switching magnetic field interaction between electrodes and neighboring electrodes that are in series or parallel electrical battery connection. In the low cell charging state, the electrodes store energy similar to a lithium battery that has the potential to self-generate an exothermal reaction if the anode or cathode is electrically shorted or under a heavy load. Once the Ni cathode is loaded with a large enough amount of Hydrogen an exothermic harmonic will produce an RF vibration that will be received by a pickup coil that sends the signal through an amplified power supply back into the electrodes to perfectly time a triggered wave form that keeps the harmonic going, like pushing a child on a swing in a continuous osculation to save electrical input energy by maintaining a harmonic osculation. In addition, a microwave transponder can be used to transmit the feedback loop and or heater source. The pulsing current, voltage and drive frequency supplied to the electrodes can be controlled for a desired rise time of the reaction to prevent thermal stress on materials. The harmonic feedback loop can vary with the reaction and fuel levels. The system will also run on a deuterium gas loaded polymer for higher efficiencies, but presently deuterium-poly is more expensive so hydrogen is preferred. Individual cells can be injection molded using conventional plastic injection molded machines shown in FIG. 11. The ions can be loaded at lower voltages.

When the present invention is arranged to act like a hybrid lithium/hydrogen battery that can be charged up, the anode electrodes can be constructed using a lithium tetrafluoroborate in propylene carbonate, dimethoxyethane, or gamma-butyrolactone, and the cathode can be constructed with lithium infused nickel plated graphite foam for a high heat and large surface area. The positive electrode gives up some of its lithium ions, which move through the conductive electrolyte polymer to the negative, Ni graphite electrode and remain there. At the same time, the hot pressurized hydrogen gases are also loaded into the nickel surfaces. At elevated temperatures the phase 2 exothermal reaction will occur, causing the resistance of the polymer to be reduced over time as the polymer becomes more conductive with an increase in joining together of crosslinked carbon.

A voltage/current feedback loop can be employed to increase or decrease the auger to supply new fuel and discharge the spent conductive graphene. The battery takes in and stores energy during this process. When the battery is discharging, the lithium ions move back across the polymer electrolyte to the positive electrode, producing the energy that powers the battery. In both cases, electrons flow in the opposite direction to the ions around the outer circuit. Electrons do not flow through the electrolyte, which is effectively an insulating barrier, so far as electrons are concerned. In addition, the heated extruder materials can be nickel, titanium, iron and lithium. With hydrogen gas and/or deuterium gas to create an exothermal reaction as the fuel is spent, the auger will replace the fuels with new reaction fuels in an oxygen free environment, thereby meeting the need for nonpolluting energy sources that do not involve health risks, and that are economically competitive with respect to oil sources susceptible to be easily discovered and exploited and naturally abundant. The fuel can be stored in plastic pellet form and heated and extruded by plastic injection molding to transform raw materials into finished products. The fuels such as Li-PE,C may need to be dried in an oven to remove moisture from the polymer, which tends to absorb moisture, so that oxygen is not present in order to prevent an explosion within the reaction chamber. In other cases the oxygen can be beneficial to cross-link the carbon bonds to make graphene.

The reactor of the present invention may also serve as a plasma discharge heat source with a microwave power supply and antenna, the coupled microwaves vibrating and heating the metal lattice to produce a microwave reaction that is picked up by the antenna and fed back into the microwave power supply for a complete closed feedback loop that keeps the metal lattice vibration in constant resonance natural vibration oscillations of transition metals and other material such as lithium deuteride in the lattice.

### DESCRIPTION OF THE DRAWINGS

FIG. 1 is an isometric view showing a coiled electro-chemical cell with an anode and cathode electrode, catalyst and electrode housing with one electrical connection point per electrode. Element 2 is an electrode in a coil. Element 4 is an electrolyte and/or a lithium-metal polymer between electrodes. Element 9 is a holder to secure the electrodes made of a non-conductive material such as ceramic to withstand high heat. Grooves 9a can also be tooling to secure the electrodes in place as an injection molding machine augur pumps a hot liquid polymer between the electrodes removing oxygen and nitrogen. The electrodes 2 and 5 can supply electrical power as a heater, battery or generator. The grooves 9a keep the electrode in alignment under heat, pressure and vibration. Elements 89,90 are alignment notches to align the electrodes and the grooves 9a and hold them in place.

FIG. 1a is a schematic circuit diagram for the series RLC of FIG. 4a, which uses a plasma to generate electricity and heat, and in which additional heat is generated between anode and cathode in Enhanced Exothermic Reactions (EERs) as hydrogen gas is loaded into the surface of the transition metals in the d-block chart at the same time using the waste heat from the RLC electrodes. The hydrogen source can be supplied externally from a tank or from a heated polymer between electrodes that provides both capacitance and a hydrogen source. Element 21 is the pickup coil between the plasma and 21a is the current switching back and forth to induce a voltage in coil 21 to produce power and a feedback signal to the power filter in 93 FIG. 1f. AC1 is an alternating current power supply, switching DC H-bridge, or switching DC power supply of the type found in FIG. 11. The RLC is in series.

FIG. 1b is a schematic circuit diagram of an electrical circuit RLC and battery storage. The resistance and capacitance is a Ni-Polymer with conductive metals or carbon and the battery is the hydrogen stored in a cathode made of graphite foam plated with nickel or other hydrogen soaking metals. The anode is a non-hydrogen soaking material so there is a difference in potential between electrodes. The electrodes are in a scroll coil to form an inductive charge L.

FIG. 1c is the same as FIG. 1b except that the electrodes are not coiled to for an inductor.

FIG. 1d is a schematic circuit diagram of a non-inductive cell with plasma and power supplied by an RC dual cell in series.

FIG. 1e a schematic circuit diagram in which the RC dual cell is in parallel with power supply AC4.

FIG. 1f is a schematic circuit diagram of the cell shown in FIG. 6, in which the inductor includes coiled scrolled electrodes 2a and 5a. The cell can be in series or parallel. The waste heat generator 46 supplies power from the over Coefficient of Performance (CoP) cell 2a and 5a back to the cell. An outside power source (not shown) starts the reaction on the surface of the electrodes. The feedback coil and power generated in 21 from the plasma 21a is filtered and the harmonic RF wave form is sent back to the power supply 46 to keep the electrode lattice in harmonic vibrations between hydrogen stored in the metal lattice and form a closed loop that powers itself and also powers the load 92. The Ni-Poly injection molded electrolyte 4, shown in FIG. 11, has both resistance and capacitance sandwiched between electrodes 2a and 5a.

FIG. 2 is a perspective view of FIG. 1 with a catalyst between electrodes having one connection point per electrodes. Elements 10 and 11 are electrical connections. Element 4 is a catalyst or a lithium-metal polymer between electrodes. Element 1 is the cell.

FIG. 3 is an electro-chemical cell wired electrically in parallel. Element 6 is an electrical screw or connection. Elements 2 and 5 are electrodes.

FIG. 3a is a perspective view of electrodes 2b and 5b, which are also shown in FIG. 3b. Alignment notches 83, 84 are aligned in a chamber with a mating post (not shown). The alignment is to prevent misalignment and shorting of electrodes. The chamber 87 in FIG. 3b aligns the two electrodes 2b and 5b. FIG. 2 is another view of two scrolls aligned with a Ni-polymer 4. The polymer fuel is not shown in this view. The back plate is machined, molded or EDM and does not have inductive properties. The scroll provides strength and high active surface area for reaction surfaces and plasma arc pitting. The semi-dielectric polymer will transport ions with the lithium or other acids such as KOH, and the carbon will provide a current path between electrodes to heat the polymer and release the hydrogen gas. A plasma arc will occur when the gas is released between electrodes. The plasma will add additional heat to cause a metal surface reaction with the presence of the lithium and transition metal groups found in the d-block table.

FIG. 3b is a cut-away view of a multi-stacked cell that is electrically connected to provide power from one end of the cell to the other in series. The electrical configuration is that of FIG. 1e. Element 87 is a ceramic or high temp housing and element 2b includes electrodes made of foamed carbon with nickel or other functional metals. Another view of electrodes 2b and 5b can be found in FIG. 3a. The voids between electrodes 5b and 2b are an Ni-Poly with carbon nanotubes or a semi conductive additive such an Ni powder. The polymer melts when electrical power is applied to 85 and 86 on the opposite end of the cell to draw power through the cell in a stacked configuration. The pickup coil 21 converts the plasma arc into usable power or a feedback loop for the power supply. The waste heat from the reaction created on the surfaces of 2b, 5b and the polymer metal (not shown) is collected in the chamber of FIG. 19 and turned into electrical power. The electrical compression connection between cells is element 91.

FIG. 4 is a perspective view of an electrical-chemical cell electrically wired in series. Element 3 is a cell.

FIG. 4a is a perspective view of two sets 2c and 5c of coiled electrodes, one inside another, with a coil. If connections 12 and 13 are tied together, then sets 2c and 5c form one electrode and the electrical ions or plasma will arc or flow between the front electrodes and through coil 21 using AC as a starting power for an H bridge DC switching power source. Element 4 is a Ni-Pe or Ni-Pe, C or Ni-Pe,Ni polymer fuel between electrodes. The scrolled electrodes produce a switching magnetic field with themselves if the electrode material is magnetic such as Ni, Fe or a combination of other magnetic metal materials. When AC is switched between electrodes 2c,5c and 7c,6d with a plasma between opposing electrodes having an opposite electrical attraction, then an aneutronic plasma arc induces a current in coil 21 to produce electrical power. Plasma current is the flow of charged particles around the donut-shaped vessel (as opposed to the random movement of the hot plasma particles). It is induced in the same way that a transformer works. The primary coil is a large electromagnetic coil in the center of the donut (its pole), and when a changing current flows through this coil, the plasma itself acts as a secondary winding and has a large current induced in it. A small electrical current is applied to the electrodes in series or in parallel.

FIG. 4b is a side view of electrodes 2c,5c, 7c,6d electrodes and fuel or electrolyte 4 between the two electrodes. The fuel or electrolyte becomes a hydrogen gas when heated externally or internally when the polymer H4,C2 is heated to a melting point and H2 is absorbed into the surface of the Ni,Fe plated electrodes with the Li carrier. Conductive coil 21 is the coil winding that captures the changing arching current or ions produced by the plasma arc.

FIG. 4c is an electrical schematic of FIGS. 4a, 4b with a plasma discharge through coil 21 to induce a voltage to supply power to the load. The capacitor, inductor and resistor will vary over time as the hydrogen is depleted in the polymer, changing the capacitance and resistance. This will affect the current in the inductor. The additional power is collected from the heat from the plasma and Enhanced Exothermic Reactions (EER) from the surface of the electrodes as the hydrogen is loaded into the metals. The power supply labeled AC1 is and alternating current supply, switching direct current H-bridge, or multi-switching supply of the type shown in FIG. 11. The RLC circuit is in parallel. Element 21a is the plasma between the two sets of electrodes 2c, 5c and 6d, 7c.

FIG. 5 Is an cut-away view of an electro-chemical multi-stacked electro-chemical cell wired in parallel with two connection points.

FIG. 6 Is a perspective view of an electro-chemical cell with an electrical connection on each end of the anode and cathode electrode with arrows showing changes in a magnetic field with an alternating current supply or switching direct current supply using MOSFETs and pulsing switching on either ends of the electrodes. Arrow 15 indicates the direction of the magnetic field, which depends on the direction of the currents at electrical connections 10,12,13,11. Element 14 is the cell. Element 15a is the reversing current direction at connections 10,11,12,13.

FIG. 7 Is an schematic circuit diagram of a switching electrochemical cell with pulsating switching Mosfets to create a switching electromagnetic field within coiled electrodes with reversing currents to generate power, store energy or heat electrodes and an electrolyte. Element 56 is a current limiting resistor to regulate current flowing between the electrodes. 81 is the reversing direction of an AC or DC current and 82 is the switching magnetic field that is in sync with the changing current direction pulsing with a counter inductive field and capacitive charge.

FIG. 8 is a switching electro-chemical cell with switching magnetic field and currents. Elements 58 and 57 are loads that are supplied with alternating on/off power. Elements 16,17,18,19 are cycling trigger pulses to switch electrodes on/off. Elements 16 and 18 are on while elements 17 and 18 are off and vice versa. Cell 14 can be used as a heater to heat the electrolyte or a battery or a heat source to turn on a Rankin style generator to produce electricity. When MOSFETs Q1 and Q3 receive a positive voltage pulse on the gate, current will flow in a clockwise direction from element 55a to 10 to 13 to 55a and when a positive voltage is on the gates of Q2,Q4, current will flow through 55 to 12 to 11 and ions or current will flow through electrolyte or conductive Li-conductive polymer 4.

FIG. 9 Is a cut-away side view cut away of a multi-stacked cell unit with outside conductive coils to generate electricity, induce radio frequencies, and act as pick up coils to be used to feed back harmonic frequencies from the reactor to the power supply, to produce a harmonic feedback loop ring. Elements 20,21,23,24,25,26,27 are coils and arrows 15c,15d,15e,15g,15h indicate natural osculations. Element 65 is a microwave cone to transmit microwaves to produce heat or a feedback harmonic osculation's heat, and 66 is an electrical connection. The reactive lattice osculation's vibrations are picked up in pickup coils 20,23,25,27 and fed back into the switching power supply amp to keep the natural osculations going, like pushing a person on a swing with perfect natural timing. The voltage can operate at alternating currents or direct currents or switching reversing DC currents.

FIG. 10 is a perspective view of multi-stacked cells with outside coils.

FIG. 11 includes a schematic diagram of a single cell with a switching power supply that keeps the polarity of the electrodes constant while switching the direction of current and magnetic fields within the electrodes on both the anode and cathode. The charging unit can act as a heater using Li-metal polymers with graphene or carbon nanotubes that heat the electrolyte to create an EER. The hydrogen from the polymer will soak into the cathode as the ions travel from the anode to the cathode within the Li-polyethylene conductive electrolyte. A plastic injection molded auger can push the conductive electrolytes between the two electrodes to and from the EER. The discharge from the cell on the non-pressurized side will be crossed linked graphene and the cathode that is loaded with hydrogen with be at a different electrical potential then the anode, as you would expect in a battery.

FIG. 12 Is a Rankin style waste heat generator that converts Enhanced Exothermic Reaction waste heat into electricity. The orifice of element 54 can house an EER cell to convert the waste heat into electrical power. Heat is generated within the orifice 54 and a pump 45 pumps the expanding hot gas into a turbine 47 that spins an electrical generator 46 so that the gas leaves the turbine 45 and is pumped into the condensing coil 53 that is cooled by a fan (not shown). The gas within condensing coil 44 is converted from a gas to a liquid where it is pumped by turbine 45 back into a closed loop Rankin system over and over again.

FIG. 13 is a cutaway view of a novel EER generator that holds pellet fuel, powdered fuel 50, or liquid fuel in a hopper 37. The auger 32 is driven by a motor 41. The auger 32 can be positively charged or negatively charged as an anode or cathode to create an EER heat reaction between the anode 32 and cathode of 38. The spent fuel is heated to a crosslinked graphene that is dispensed into a chamber 34 out of the nozzle 31. A heat exchanger 33 will heat a fluid or a gas to spin a turbine to produce electricity (not shown). The entire system is closed and vacuumed or pressurized using argon or a fuel gas such as hydrogen. The auger 32 can by continuous or intermittent depending on a temperature feedback loop (not shown). The spent cross linked graphene can produce a wire or other shaped profile depending on the shape of nozzle 32. A continuous winding spool (not shown) can be placed inside of chamber 34. Powered fuel 50 may be an Li-Pe powdered fuel.

FIG. 13a is a novel pre-extruded Li-polymer filament 88 with nano-nickel powders and iron powders on a spool 87 that is loaded into the augur 32 with drive rollers 89 that are driven by a stepper motor (not shown). The pre-extruded fuel has advantages in space where there is no gravity to load the hopper or on a moving vehicle were vibration may affect loading of the hopper. The auger is driven by a motor 41 shown in FIGS. 13, 16, 17, 14, 15, and 19 and is positioned inside a heated tube 38 where the loaded fuel is converted by a heat reaction and electricity or other heat source as needed. The filament fuel in stored in an oxygen-free and or gas-loaded environment or vacuum chamber (not shown). A motor controlled feedback loop that controls the motor (not shown) to drive the drive sprockets 89 will advance the fuel 88 as the temperature decreases over time at a controlled rate of speed to keep the reaction temperature constant.

FIG. 14 is a profile view of FIG. 3 with the Rankin waste heat conversion of FIG. 12 using a continuous or intermittent EER auger fuel delivery system that produces graphene waste to produce an electrical wire or other materials.

FIG. 15 is a profile backside view of FIG. 14, showing a condenser fan 48a and fan motor 48. Tubes 52 and 51 are used to supply a gas or are connected together to keep an equal pressure within the system. Tube 52 can also be an argon or CO2 supply line to drive an air-motor that drives the auger.

FIG. 16 is a cutaway view of FIG. 13, where element 60 is internal magnetics and 61 is an external magnetic drive unit driven by a gear motor (not shown) that is connected to a coupler 62. Element 33 can be a waste heat exchanger or inductive heater, and element 63 embedded in the ceramic can be an electrical heater or heat exchanger.

FIG. 17 Is a perspective view of FIG. 16.

FIG. 18 is a perspective view of a honeycomb reaction chamber similar to a catalytic converter with a high reaction surface area. The ceramic membrane inner walls are plated with any one or combination of Pd, Pt, Ru, Be, Ni and the fuels are Li-polyethylene, hydrogen, methane with or without graphene or carbon nanotubes, or graphene that is functionalized with or without a peroxide. The Li-PE fuels can also contain Ni powders. The porous membrane is filled with an Li—Ni fuel using a heated injection molding auger or heated cylinder pump and can act as a standalone reaction chamber using an external electrical heater, flame or electrical opposing electrodes on each end of the chamber to heat the reaction chamber using a conductive polymer and electrical AC or DC or pulsing DC current flow. The cell can have a continuous flow of fuel or be a one-time standalone use. Element 68 is the ceramic or high temperature material cell and 70 indicates inner chamber through-holes that provide a high active surface. The holes 70 can be filled by an Li-Poly with transitional metal fuel or hydrogen, deuterium or methane gas under pressure. The walls of through-holes 70 of cell 68 can be pre-coated with Li, Ni, Fe, Ti, Mn, Fe, Co, Ru, Rh, Pd, Ag, Ta, W, Re, Ir, Pt, Au, Bh, Cn or Li alloy of the same metals using many different electroplating, gaseous plating, or plasma plating methods.

FIG. 19 is a cut-away view of FIG. 18 with an internal Nichrome resistive or water cooled inductive heater 71 having a steady state or switching frequencies within a chamber to apply heat to the honeycomb cell 68 and a heat exchanger 69 that will capture the EER heat and transfer the heat to pumped hot gas or fluid of a larger Rankin waste heat recovery system outlined in FIG. 12. The system 49 produces electricity or is used as a heater from the exothermic heat reaction generated in chambers 40 to heat the fluid or gas. Once the Coefficient of Performance is more than 3 to 4, the system will run itself with excess electricity or hot fluid and/or a gas in a closed loop system. The fuel stored in hopper 37 flows into auger 32 and is heated with inductive or resistive heaters 33. The melted fuel is injected into the tubes 68 and heated by heater 71 in the chamber 40. The waste heat recovery heat exchanger 69 heats the fluid or a gas to make electricity with a turbine or thermoelectric modules, or to heat hot fluids.

FIG. 20 is a cut-away view of a ceramic or high temperature honeycomb battery 68, or heat reactor, with the inner walls 70 plated with metals such as Ni, Fe, Ti, Mn, Fe, Co, Ru, Rh, Pd, Ag, Ta, W, Re, Ir, Pt, Au, Bh, Cn or a Li-ahoy of the same metals using many different electroplating or gaseous plating methods. The reactor or battery is filled with a hydrogen or deuterium gas, or liquid or injection molded Li-PE with a carbon such a graphite, carbon nanotubes, or grapheme flakes, either functionalized with or without a peroxide. The electrical endcaps 72 and 73 have a step 83 to drive an electrical current through the conductive Li-Pe, carbon based polymer to heat the Li-PE into a hydrogen gas that get absorbed into the walk 70 to create an exothermic reaction above the input current over time. The high heat from the reaction separates the H4C2 into hydrogen and carbon. The high temperature carbon under an electrical charge turns into cross-linked or un-crossed linked graphene. Vent holes for loading and unloading of the conductive Li-PE are indicated by 76 and 75. The gaps 74 and 76 ensure a cross flow of injection molded resin with a step in the end caps 83 to create a gap that removes air during the loading process or extrudes fuels and creates an electrical current path between caps 72,73. The reactor 68 can be gas flushed with H2 or argon before the injection molded filling takes place.

FIG. 21 is a tube 78 with two electrodes 79,80 that forms a barrel for an extruder. The porous or solid electrodes are plated with Ni, Fe, Ti, Mn, Fe, Co, Ru, Rh, Pd, Ag, Ta, W, Re, Ir, Pt, Au, Bh, Cn or a Li-alloy of the same metals using many different electroplating or gaseous plating methods. The electrical charge between 79,80 can be AC, DC or pulsed DC during the extrusion of an extruder such as shown in FIGS. 16 and 32. The charge on electrodes 79,80 can be positive and the auger 32 can be negative or auger 32 can be positive and electrodes 79, 80 can be negative or any other combinations. Electrode 79 may be a conductive or non-conductive material. The electrodes 79,80 soak hydrogen from a Li-PE carbon or metal conductive material and an additional heater can be used on the outside surface of tube 78. The spent fuel is graphene or graphene with conductive metal powders such as Ni, Fe, Ti, Mn, Fe, Co, Ru, Rh, Pd, Ag, Ta, W, Re, Ir, Pt, Au, and/or Bh. Element 84 is a hole that accept the auger 32.

FIG. 22 shows a homogeneous heated aqueous colloidal suspension of the cross-linked oxide sheets generated by addition of polyallylamine with lithium salts and Poly, suspended in a aqueous colloidal suspension under an electrical positive/negative charge, with or without a constant or switching magnetic field, and with or without Nitrogen used as a carbon graphene cross linker.

FIG. 23 is an extruded graphene waste product from Enhanced Exothermic Reactions. The rollers 96, 97 shape the graphene and align the crystal structure of the metals and assist in the alignment of the cross-linked graphene. The rollers both shape and pull the extruded filaments to compress to enhance the fibers strength and improve the conductivity. The interworking can be found in FIG. 13. The extruded profile can be a filament or sheet form.

FIG. 24 is cut-away view of a filament feed for supplying fuel into an EER plasma reactor. The rollers feed the filament into a porous ceramic membrane. At each end of the membrane are electrodes. An RF current carried between the electrodes heats the conductive polymer fuel feed stock to produce a hydrogen gas that escapes through the ceramic membrane and produces a plasma in the plasma chamber to add additional heat to the EER reactor.

FIG. 25 is a cut-away close up view of the filament feed fuel supply of FIG. 24. The fuel 99 from a spool is loaded into the reactor through a porous ceramic membrane 100 and an electrical current flows through the filament fuel between electrodes 102 and 101 to heat the polymer fuel, which contains lithium, nickel, iron, graphene, and/or carbon nanotubes (CNTs) and acts as a heater to convert the polymer into hydrogen gas that penetrates the ceramic membrane into the plasma zone 103 to produce a plasma between electrodes 102 and 101. The spent fuel 98 is graphene that is rolled into a spool. The RF power supply 106 supplies the current flow between the plasma and conductive filament fuel to act as a first heater and the plasma acts as the second heater to produce an EER effect. Thermoelectric modules 105 are on the outside of the EER reactor to convert heat into electricity. The holes 104 enable heat exchange to heat a gas or liquid to spin a generator to produce electricity. The discharge port 107 can be used as a rocket engine on a space craft.

### DESCRIPTION OF PREFERRED EMBODIMENTS

Introduction

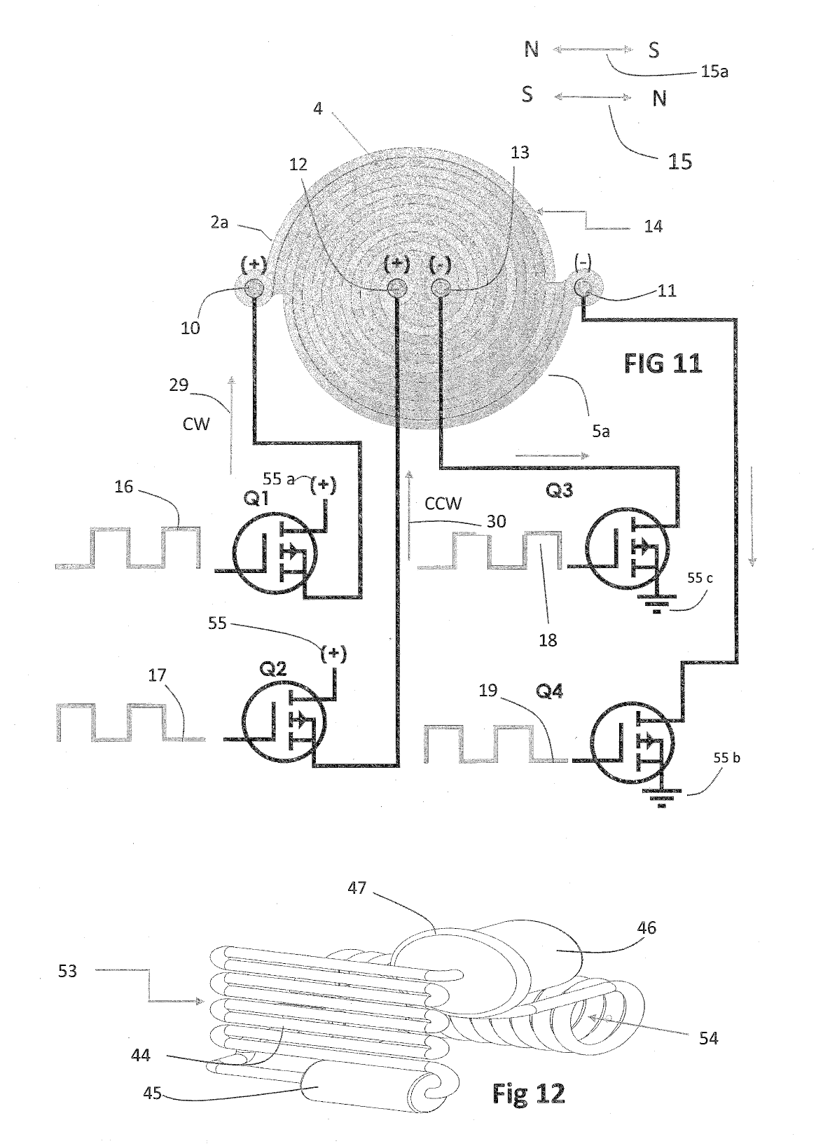

Preferred embodiments of the present invention control dissolving the reactive gas (e.g., hydrogen, deuterium, methane, or polymer-gas; often referred to as fuel gas, polymer or simply fuel) in a transition metal lattice structure for the purpose of producing industrially useful heat, electricity and energy storage while producing a cross-linked or non-crosslinked graphene using an auger. The lattice structure can be a self-supporting shape (e.g., wire, slab, tube, metal powders, foam conductive materials such as carbon graphite, Fe—Ti, Mn, Pd, Ni plated on the surface of silica crystals) of solid, sintered or foam materials, or can be material or a carbon graphite porous material with deposited nickel, iron-titanium, magnesium or palladium deposited on a support structure. Further, the lattice structure can include powdered or sintered material that relies on a supporting or containing structure in a sitting bed, fluidized bed, packed bed format or formed into a coil inside of a coil to produce a magnetic field and counter electro-motive force within a cell with switching magnetic fields. An auger is used as a pump and/or pump and electrode to transport a fuel source of lithium-polyethylene C2H4, graphene, carbon nanotubes, methane CH4, or conductive metal powders with or without an organic peroxide for a CNT crosslinked “Reactant Source” 4 as labeled in FIG. 11, and electrodes 2a, 5a. Embodiments of the present invention provide a selected inert carrier gas such as helium or argon to deliver the reactive gas at appropriate temperature and pressure conditions over or through the material in combination with appropriate harmonic feedback stimulation. The enclosed invention can use methane in combination with landfill Poly plastics powder from discarded trash to produce electricity and extruded conductive graphene by converting the carbon into graphene at elevated temperatures, gas, and hydraulic pressures, and load the hydrogen into the metal electrode lattice to form an exothermic reaction and harmonic vibration. A start-up electrical AC,DC, solar or gas flame power supply is required to heat up and trigger the lattice heat reaction, and once the lattice reaction is triggered more energy output is observed than energy input, measured in Coefficient of Performance (COP) that is the ratio between energy output and input in an electrochemical triggered heat reaction. As a result, the invention will run itself until the fuel is spent. The polyethylene can contain an organic peroxide to cross link the graphene and CNT's for energetics applications. Any of the transition metals below can be used in combination or indivisibly to trigger a hydrogen or deuterium reaction if loaded properly. The electrodes can be produced from a variety of materials, including the preferred foam or powder, which has a high surface area. Another novelty of the invention is to oxidize the surface of nickel foam or graphite foam and grow carbon nanotubes inside the cavities of the oxidized honeycomb surface and then to carbonyl a thin layer of nickel or Ti over the carbon nanotubes for an increased surface area with an active EER reaction similar to that described in U.S. Pat. No. 8,912,522, except that the improved carbonyl layer over the carbon nanotubes is used to enhance the vibration of the surface of the nickel, Fe, Ti reaction, which is not described in U.S. Pat. No. 8,912,522 intent. The carbon nanotubes can also form on the surface of the bare nickel or graphite surface in the presence of heat, carbon, and magnetic fields, and on the cross-linked graphene waste materials leaving the extruded augers output.

Transition metals in the d-block

| Gro | | | | | | | | | | |
|---|---|---|---|---|---|---|---|---|---|---|
| up | 3 | 4 | 5 | 6 | 7 | 8 | 9 | 10 | 11 | 12 |
| Period | Sc | Ti | V | Cr | Mn | Fe | Co | Ni | Cu | Zn |
| 4 | 21 | 22 | 23 | 24 | 25 | 26 | 27 | 28 | 29 | 30 |
| Period | Y | Zr | Nb | Mo | Tc | Ru | Rh | Pd | Ag | Cd |
| 5 | 39 | 40 | 41 | 42 | 43 | 44 | 45 | 46 | 47 | 48 |
| Period | 57 | Hf | Ta | W | Re | Os | Ir | Pt 77 | Au | Hg |
| 6 | = | 72 | 73 | 74 | 75 | 76 | 77 | 78 | 79 | 80 |
| | 71 | | | | | | | | | |
| Period | 89 | Rf | Db | Sg | Bh | Hs | Mt | Ds | Rg | Cn |
| 7 | = | 104 | 105 | 106 | 107 | 108 | 109 | 110 | 111 | 112 |
| | 103 | | | | | | | | | |

System Topology

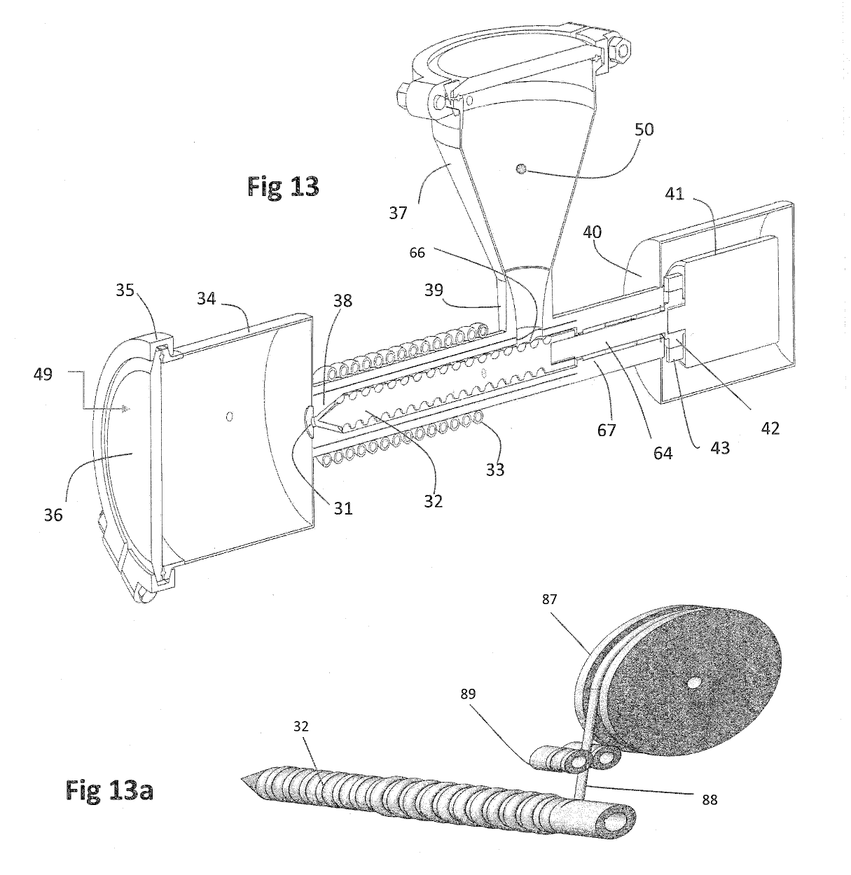

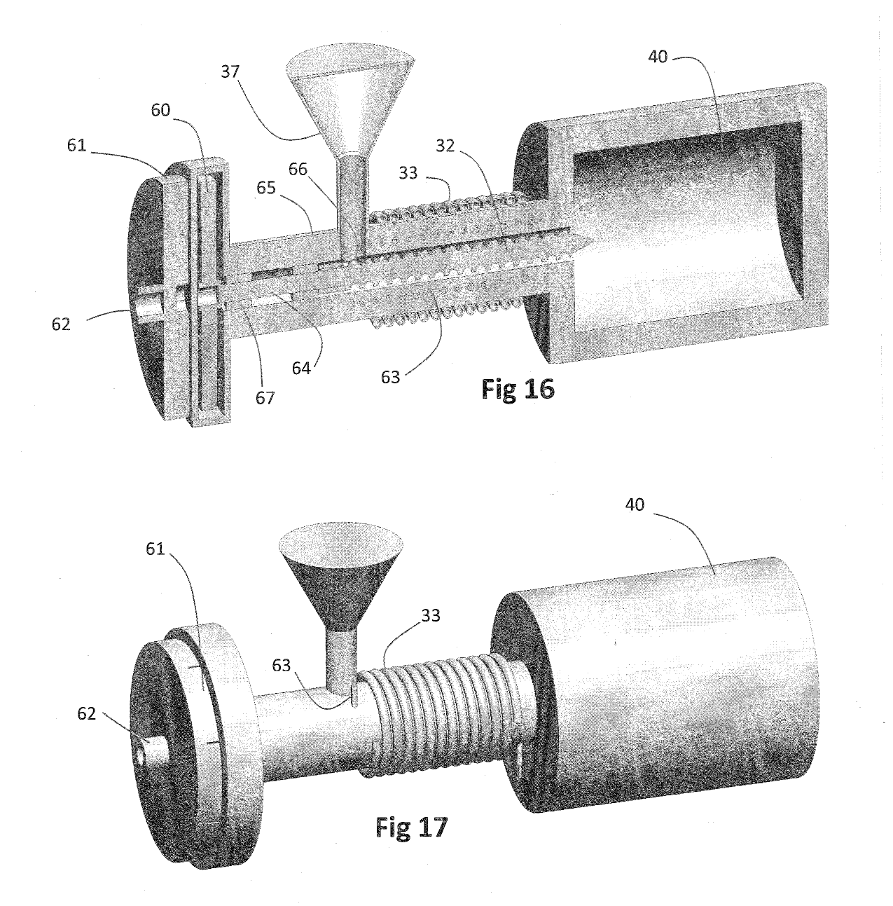

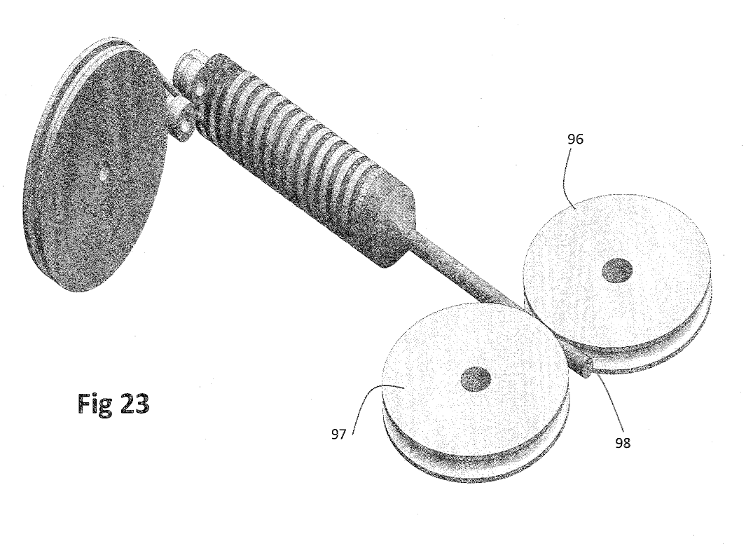

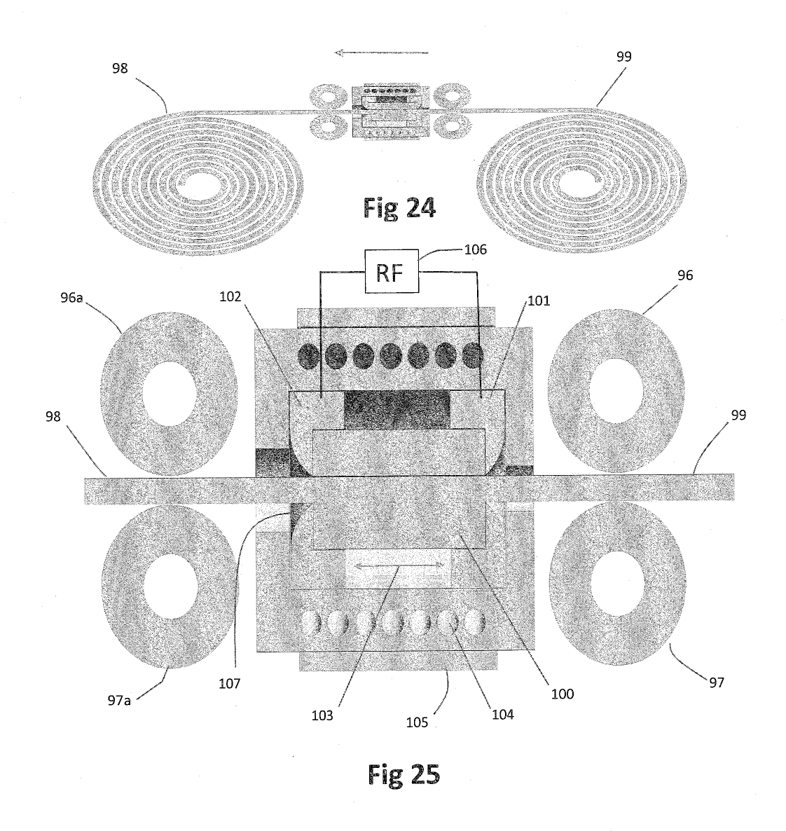

As shown in FIG. 16, the closed system is argon flushed first to remove oxygen. The auger 32 is rotated by a temperature feedback loop electronics (not shown) or motor controller controlled by a computer that spins a gear motor (not shown) that is connected to shaft input 62, which spins a magnetic plate 61 that is magnetically coupled to magnetic or steel plate 60. Magnetic or steel plate 60 rotates a seal-less shaft 64 that is supported by bearings 67, which spins an auger 63 that transports fuel (not shown) located in a closed hopper 37 into the tube 65 for heating by a heater 63 in an auger loading zone 66. The exothermic reaction takes place in the center tube 65 under both gas pressure and mechanical, hydraulic screw pressure surrounded by the heater 63. The reaction fuels can be Li, Fe, Ti, Pd and nickel or titanium powders with a hydrogen or methane gas, or a fuel such as lithium-polyethylene powders with nickel powders or plated Ni silica crystals. Additional hydrogen or methane can be supplied externally or the hydrogen gas can come exclusively from the polyethylene as it off gases under temperature and pressure. The fuel fills a heated tube 65 with a fuel (not shown) that is stored in hopper 37. The exothermic heat generated using lithium nickel, Fe, Ti metal powders or Li-polythene nickel powders turns the spent carbon into graphene that is extruded into chamber 40, from which the graphene can be extruded into wire or other sheet profiles (not shown). The inner wall 65 can be nickel plated with other reaction metal coatings such as Pd, Ru, Ti, Fe, or Mn to act as a reaction chamber. FIG. 13 shows a collection chamber 34 to store the extruded graphene waste products, as further shown in FIG. 23.

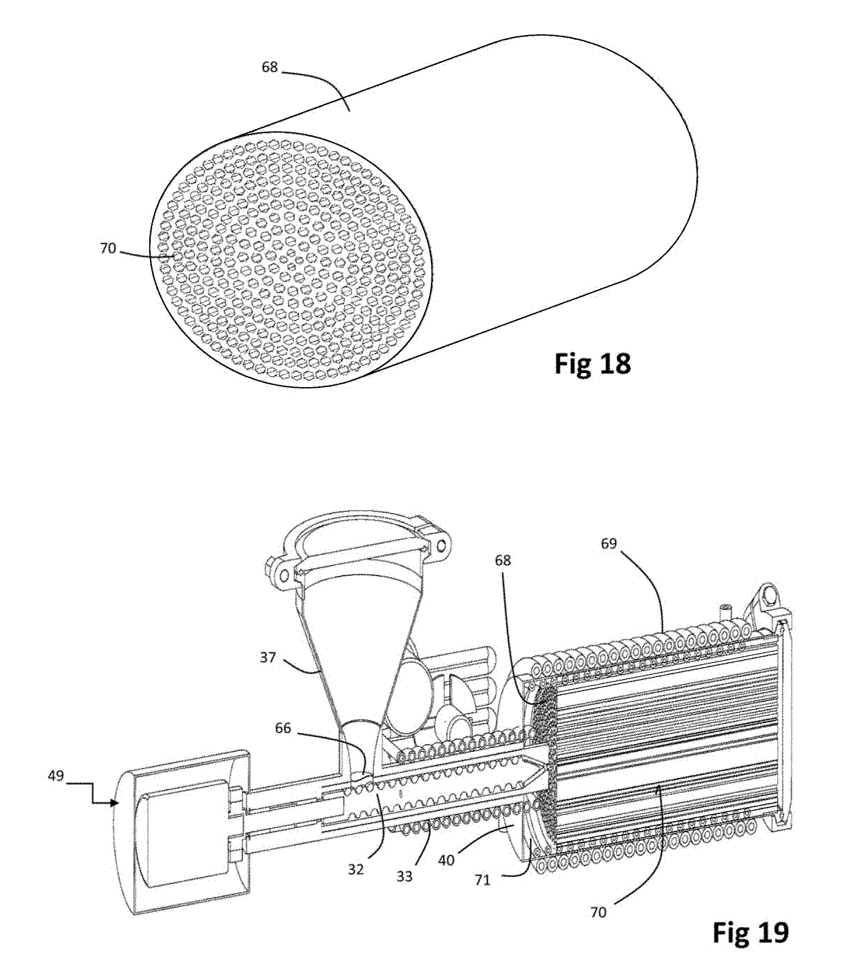

As shown in FIG. 19, fuel stored in the hopper 37 is loaded by gravity feed or by another auger (not shown) into tube 66, where an auger 32 feeds the fuel into a heated area where it is heated by heater 33 and melted into a liquid Li-Pe with a carbon or transition metal powder. The melted polymer is pumped into the holes 68 and heated by the heater 71. The waste heat recovered by heat exchanger 69 is pumped to a turbine to make electricity or heat a fluid or gas such as a hot water heater. The Li-Pe fuels can be extruded in large sheets and transported safely and loaded into a grinder at the power plant that transforms the raw sheet material into a powder to be fed into an auger 32. The cell 70, also shown in FIG. 18, can be used as a standalone reactive cell and replaced when the fuels are used up in a manner similar to a disposal battery. As shown In FIG. 19, an external heater 71 may be used.

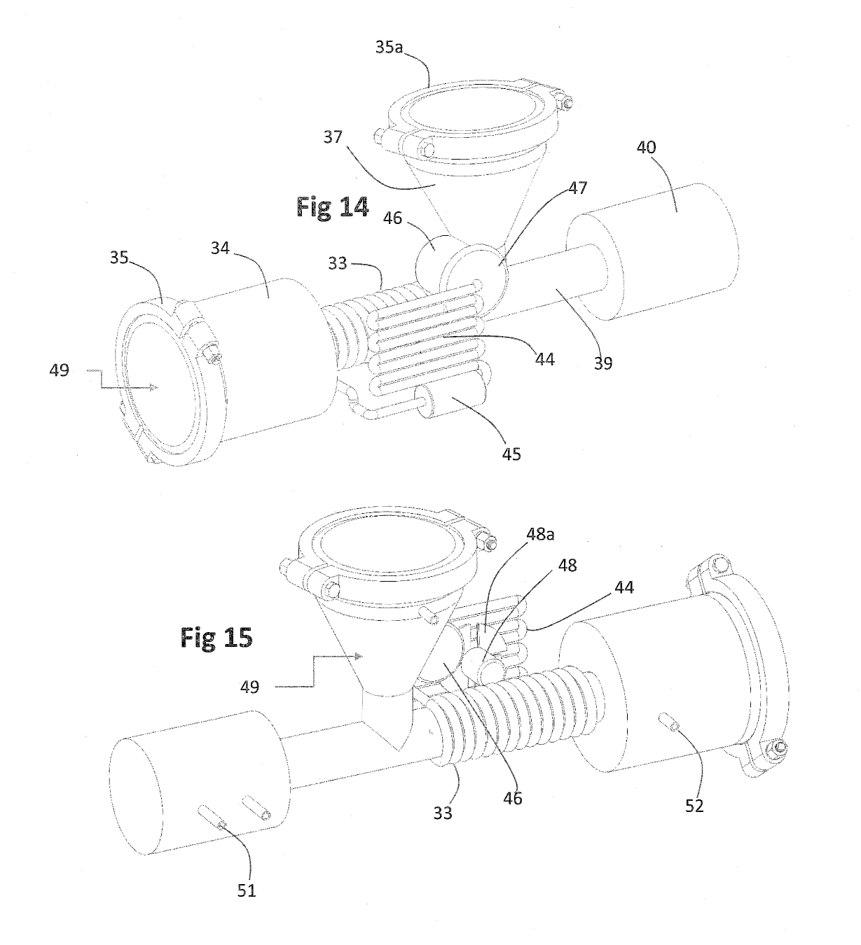

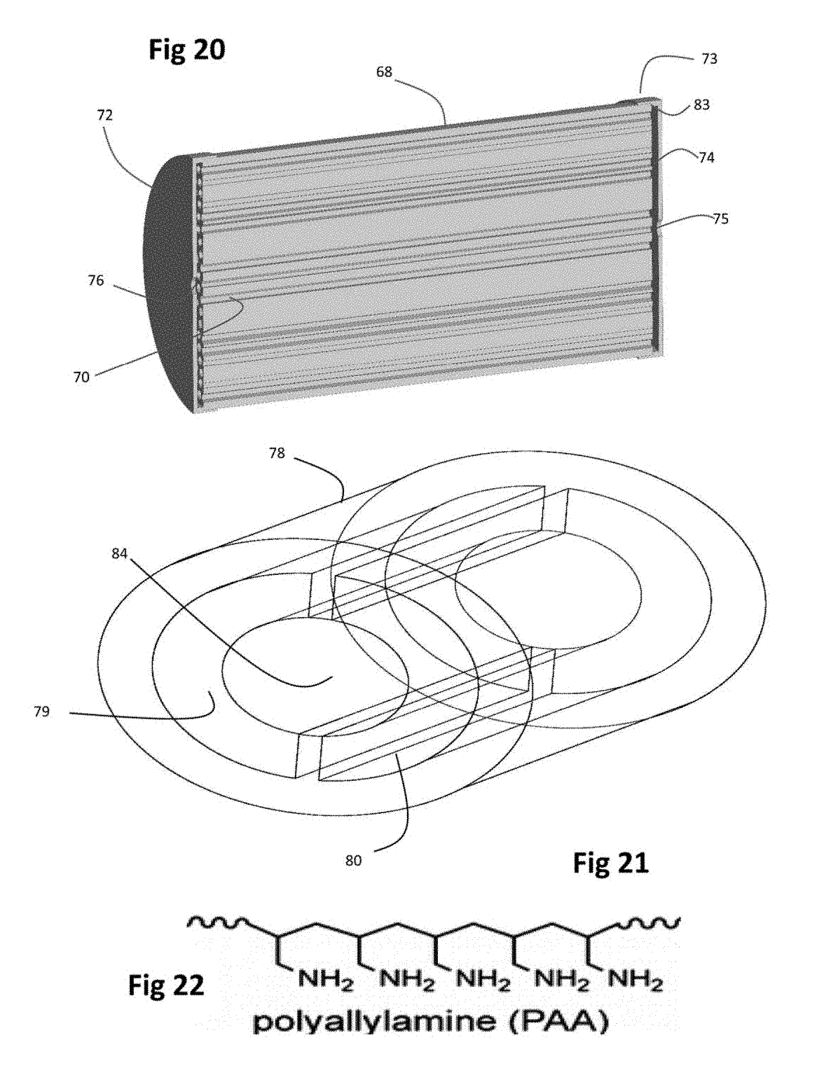

As shown in FIG. 20, an internal Li-conductive polymer can be used inside of chamber 40 to heat the reactor more efficiently. For example, nichrome resistive wire is 40% less efficient as a heater source then conductive polymers using carbon nanotubes or graphene. By heating up the polymers with an electrical charge, power is saved and the electrical current joins the carbon chains together during the reaction heated process. FIG. 21 shows a reactor barrel that accepts an auger 32 (not shown), which has two electrodes 79,80 to pass a current through the melted Li-Pe conductive polymer that is pumped by auger 32 shown in FIGS. 19, 16, 17, 14, 15, and 13 to produce heat and graphene. The electrodes are made of solid or porous conductive materials such as graphite plated with a transitional metals such as Ni, Fe, Cu, or Ti. FIGS. 14 and 15 are perspective views of a Rankin style heat recovery system that deploys a motorized auger with an electronic feedback loop (not shown). Once the reactor is running, a temperature reading is taken of the heated gas or liquid in the heat exchanger. A lower temperature is an indication that the fuels are depleting and, in response, the auger advances the fuel into the heated auger reactor to keep a constant temperature within the reaction chamber. The same feedback loop can be used in FIG. 19. The difference between FIG. 16 and FIG. 19, is that in FIG. 16, the reaction takes place within the auger tube 65 and the graphene is dispensed inside of the chamber 40. In FIG. 19, the reaction cell 68 and the liquid polymer is being fed by the auger 32. Not shown is that the liquid Li-Pe spent heated fuel in 68 can be pushed under hydraulic pressure by the auger 32 into a separate chamber for graphene recovery, or into an extruder head to produce an extruded profile such as wire.

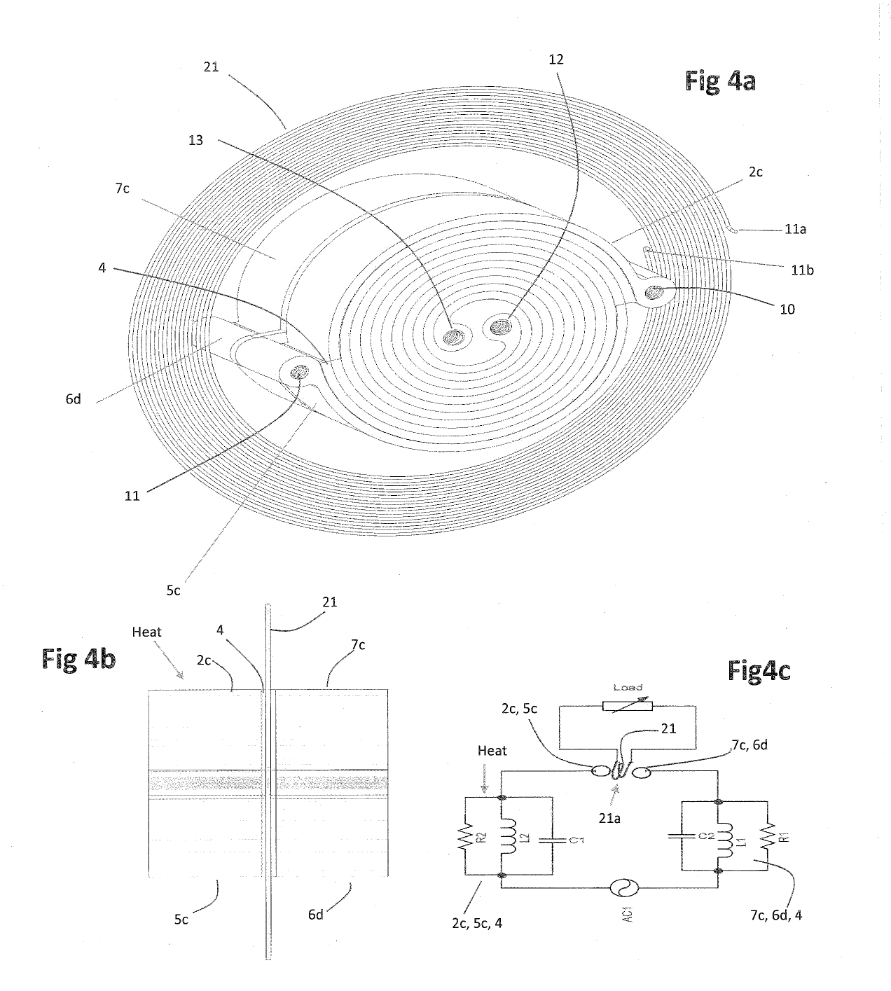

In another embodiment shown in FIG. 4a, the plasma current is the flow of charged particles around the donut-shaped vessel as opposed to the random movement of the hot plasma particles. It is induced in the same way that a transformer works through coil 21, and the inductive-capacitive storage within the capacitive energy is stored in the polymer. All inductive energy is stored and released between electrodes as the coils switch current direction using AC or H-bridge DC circuits. The primary coil is a large electromagnetic coil 2c,5c and 7c,6d in the center of the donut (its pole), and when a changing current flows through this coils, the plasma itself acts as a secondary winding and has a large current induced in it. Plasma current is crucial to the operation of the cell in FIG. 4a in two ways. Firstly, the induced current actually starts the plasma off and gives it its initial heat to melt the polymer to release hydrogen gas to form the plasma, in an effect known as ohmic heating. Secondly, the current creates a poloidal magnetic field, which combines with the toroidal field created by the coils around the cell's vessel to create a magnetic field with a scroll twist. This scroll twist is vital for confining the hot plasma rushing around the cell, because without it the particles would drift outwards and collide with the outer walls of the vessel and not induce a current in coil 21 to generate electricity. The additional electricity can be used as an over Coefficient of Performance to keep the cell running in a loop. Once the plasma is created by the coils' large electromagnetic fields, it must be constantly heated, to replace energy that escapes the confinement of the plasma, which is far from perfect. But as pointed out above, the plasma current requires a changing magnetic field. In other words, the cell can only run until the cons reach maximum current. The pulses are short. In this time, a large amount of energy is required to maintain the reaction, which was studied and on which experiments were conducted to try and improve its performance. The coils in FIG. 4a are porous graphite with a nickel coating or titanium coating, with or without 1% Fe. The graphite electrodes can withstand the hot plasma arc and the nickel plated electrode surfaces are hydrogen loaded on the surface to create a hydrogen embrittlement at a pressurized state of an unbalanced lattice to create an EER heat that is greater than the input energy to heat the cells fuel and at the same time release a plasma (which is not found in the reactors of U.S. Pat. No. 7,736,771 or U.S. Patent Publication No. 2014/0332087.

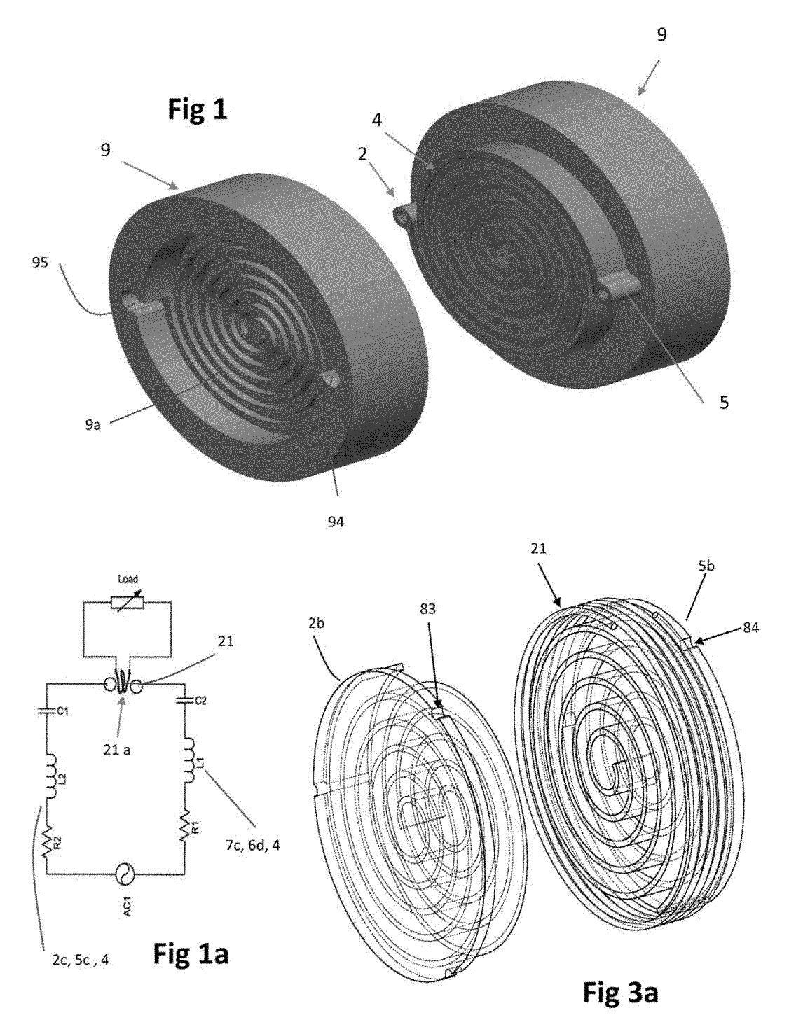

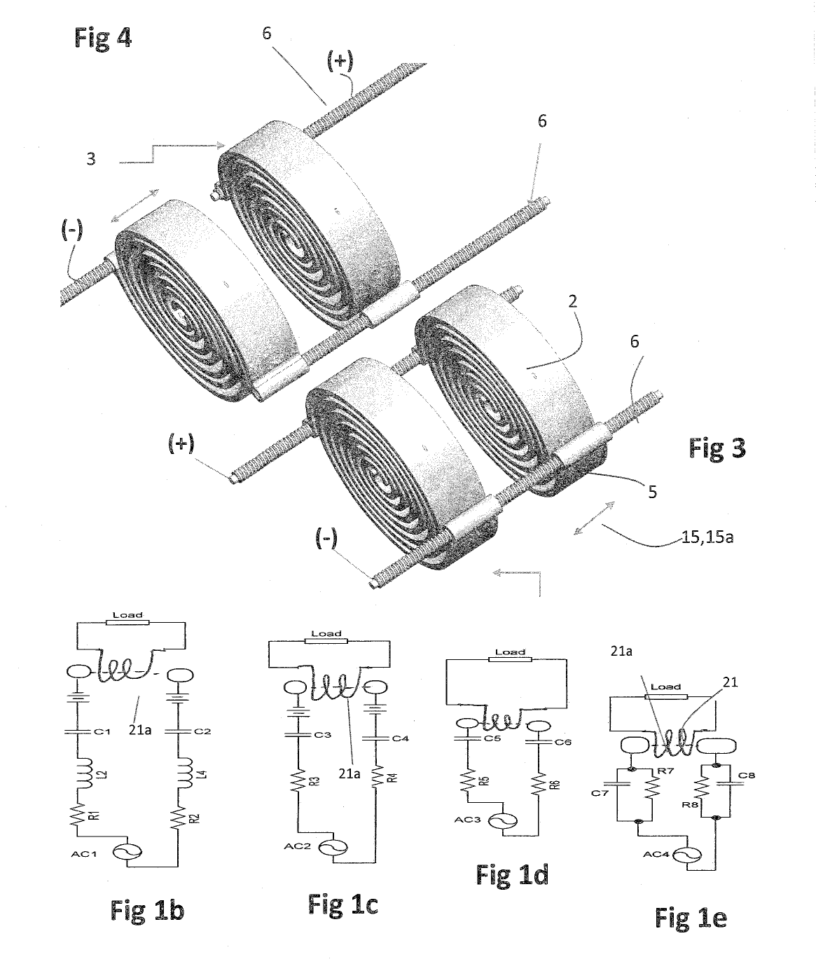

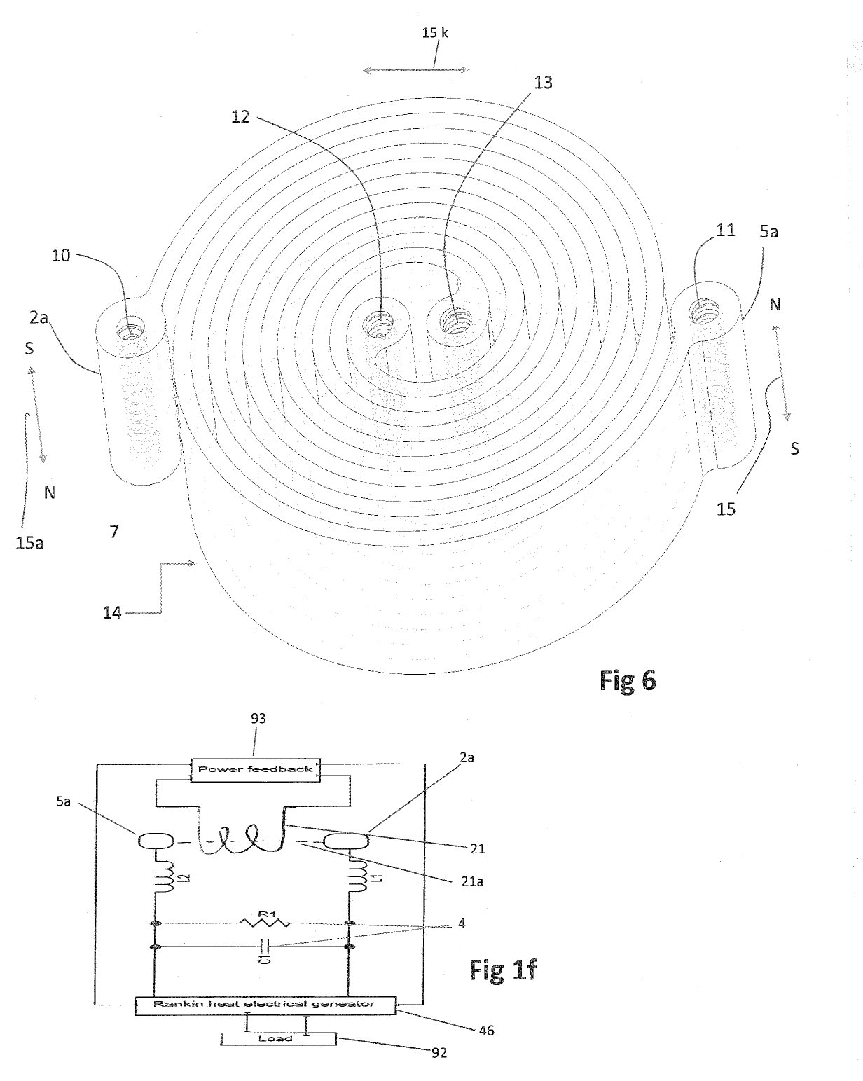

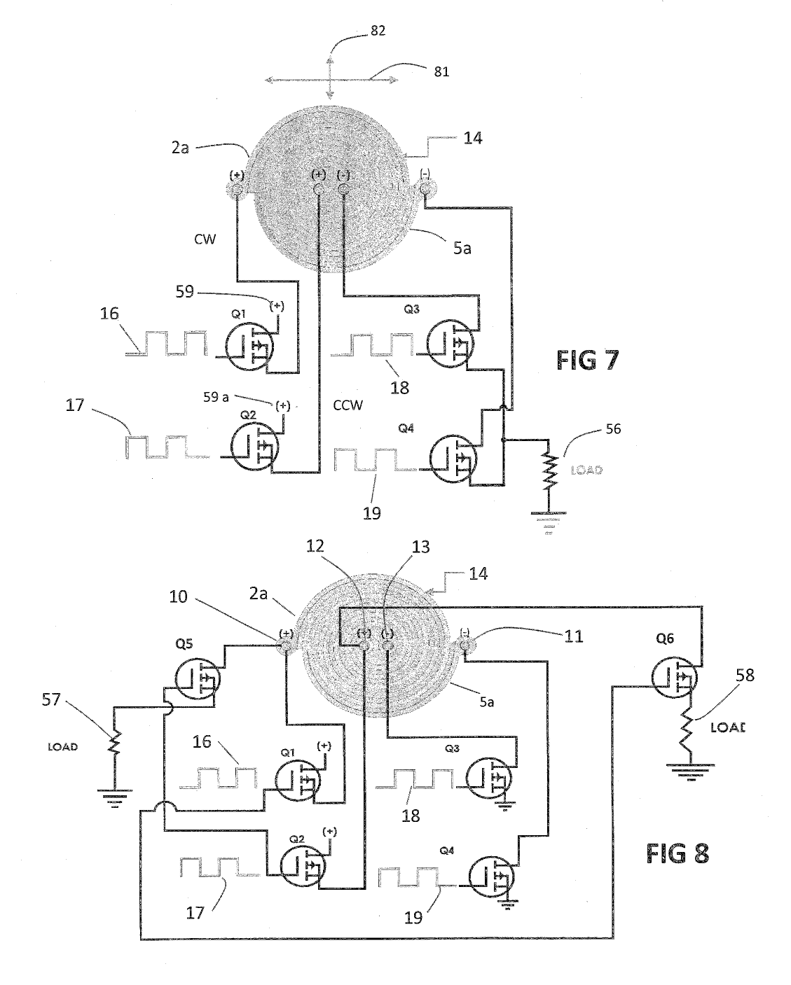

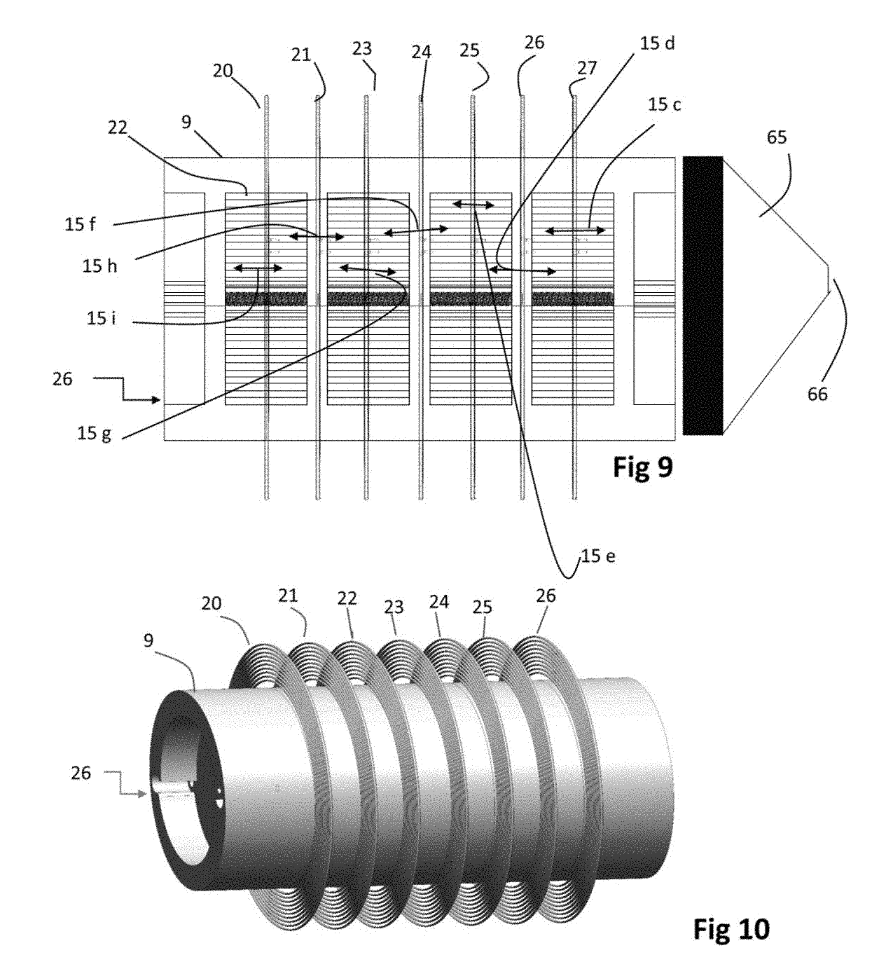

FIGS. 3 and 4 show a cell as a battery. FIGS. 9 and 10 show coil locations for the cells of FIGS. 1, 2, 4a, 4b, 5, 6, and 7. The coils can be used to transmit RF or receive RF for feedback loops or collect induced electromotive forces to produce power between the interactions of the cells. The switching inductive reversing coils use AC or other methods to produce a secondary counter Electromotive Force (EMF) plasma spike not found in non-inductive electrode coils. In FIGS. 4a and 4b, if electrode 5c is connected to AC neutral and electrode 2c is connected to AC positive, and at the same time electrode 6d is connected to AC positive and electrode 7c is connected to AC neutral, both cells will act like charged capacitors that discharge a capacitor discharge plasma arc between electrodes 5c, 2c and 6d, 7c and at the same time between the coil 21 to arc between cells. The counter EMF capacitive spikes will improve the performance of the cell's plasma and electrical generating efficiencies. The plasma will fire on each sine wave cycle, DC H-Bridge cycle, or switching DC cycle of the respective arrangements shown in FIGS. 11, 7, 8, 3, 4 and 5. In FIG. 8, the capacitive electrical discharge loads can alternate between outputs 57 and 58. In FIG. 7, output 56 can also be a current limiter.

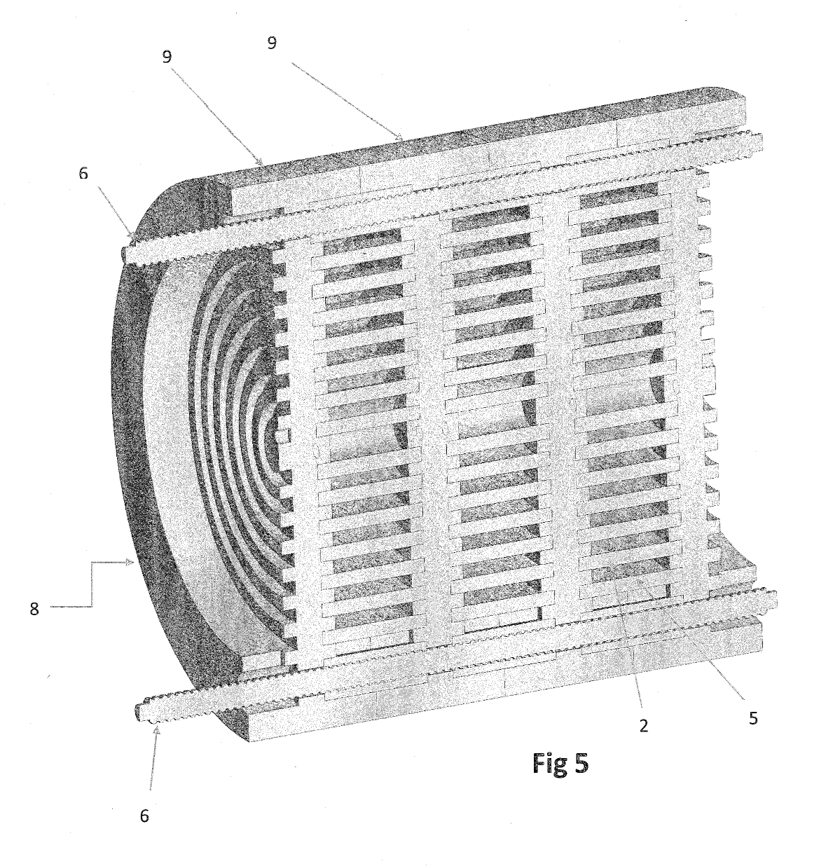

FIG. 5 shows a stack of the cells of FIG. 3 arranged in a row. As in FIG. 4, the (+) and (−) connections can receive AC currents, switching H-Bridge DC currents, or the currents shown in FIG. 11, in which the currents reverse direction but not polarity. As the current switches in FIG. 4a using reversing currents with steady state polarity or reversing polarities and reversing currents such as AC, the direction of magnetic fields also reverses as shown in FIG. 6 by arrows 15, and 15a, and again in FIG. 7 by arrows 82 and 81, which are perpendicular to current flow and magnetic field direction. In addition to electricity generated in the plasma cell found in FIG. 4a, heat is also recovered and turned into additional electricity as shown in FIG. 19, in which the honeycomb cell of FIGS. 4a and 4b is replaced or added to fit the plasma cell found inside of chamber 40 of FIG. 19 to convert additional waste heat into electricity. FIG. 4c is an electrical schematic of FIGS. 4a and 4b, in which the AC1 power supply or other switching power (not shown) is used to power two or more sets of the electrodes, 2c,5c and 7c, 6d. The Ni-Pe dielectric material 4 forms a capacitor with nearby parallel electrode 7c,6d. Connections 12 and 13 can be tied together to form one electrode per cell or they may be open to form anode/cathode pairs 2c,5c or 7c,6d for each cell.

The inductance and magnetic fields can change depending on whether the electrode coils are wound in the same direction or opposite directions, or are just a single wound coil. The coiled electrodes build up a charge and discharge a plasma arc between a coil in a hydrogen gas to produce electrical power induced in the coil, and at the same time waste heat is generated from the Enhanced Exothermic Reactions (EERs) of the hydrogen loading into the electrodes to form a surface exothermic reaction that is recovered by the Rankin cycle unit found in FIGS. 12, 13, 14, 15, 16, 17, and 19 to produce electrical power or hot water.

FIG. 1a is a series RLC wired as shown in FIG. 4a. The impedance will change as the Poly heats up with a resistive carbon, metal powders or external heat source that will also have an effect on the capacitance of the material. The plasma arc will change with input voltage change and RLC variables when gas loading takes place into the lattice, which will cause an additional RF disturbance in the RLC network. Additional hydrogen fuel can be loaded into the cell from a storage tank (not shown). A natural harmonic RF resonance can occur within the lattice of the electrodes that would be beneficial in vibrating the lattice between the two cells that interact with the arcing plasma at a continuing harmonic vibration to keep the vibrating lattice in motion, similar to a swing in motion on a playground swing set. The capacitance is beneficial in storing and releasing electrical energy into the lattice and plasma in each reversing cycle.

In the reactors of FIGS. 4a to 4c, the material used as polymer 4 can also be polytetrafluoroethylene (PTFE) containing a fraction of pendant sulphonic acid groups with or without lithium to form the basis of the proton exchange membrane and or a photon exchange between electrodes.

FIG. 13a is a spool 87 that houses a filament of extruded lithium, polyethylene with or without conductive materials such as carbon nanotubes, graphene flacks, nickel powders, titanium, iron, magnesium or other combinations of transition metals found in the d-block table. The extruded filament fuel 88 is pulled by friction wheels 89 driven by a motor (not shown) in an intermittent or continuous manner and pulling wheels 96,97 shown in FIG. 23. The fuel filament is fed into an auger to prevent clogging in a heated tube of the type shown in FIGS. 13, 23, 19, 17, 14, 15 and 16.

As shown in FIG. 16, the heater 63 melts the Li with nano nickel or titanium powders with 1% Fe to create a heat reaction in the tube 65 caused by an EER with gas loading on the surface of tube 65 or in the Ni, Ti, Mn, Ni, Ti, or Mn coated on the surface of Rf quartz crystals. As the fuel is converted into hydrogen and carbon, the hydrogen is soaked into the metals and the waste carbon is converted into graphene and crossed-linked graphene. The fuel in the reactor of FIG. 16 is input to tube 66 and advanced by an auger 32. As shown in FIG. 13a, the fuel supplied to the reactor of FIG. 16 may be extruded as a filament 88 by friction wheels 89, which are rotated in step with the auger motor based on the temperature of the reactor. As the reactor in FIG. 16 starts to cool, the auger advances the spent fuel as graphene from heated tube 65. The heat generated by the fuel 88 is captured in a heat exchanger 33 that is part of the Rankin electrical generator of FIG. 12. A constant supply of hydrogen or methane can be supplied to the reactor externally. Methane contains carbon that will cross-link with the carbon in the Pe. Another advantage of the filament feed of FIG. 13a is that the filament feed fuel does not require gravity to load the fuel into the auger, or in some cases an auger is not required if the friction drive wheels are deployed in a manner similar to 3D printing. The filament fuel delivery system has an advantage in supplying power and heat for space generator applications and moving airplanes, marine and land vehicles. In addition to continuous extruded shapes, other injection molded rings, bullets and other shapes can be molded into solid safely handled fuels. Lithium hydride metals are very dangerous when exposed to oxygen and moisture, but encapsulating the lithium in a polymer with nickel, Fe and other transition metals makes it safe to store in atmospheric oxygen environments. The Poly fuels need to be kept in a dry environment to prevent moisture from being absorbed into the polymer. Post curing with an oven will remove the moisture content before loading the fuel into an oxygen free reactor. The lithium polymer with Teflon and H2O or oxygen will produce a propellant or energetics reaction. The fluorine from the Teflon will act as an oxidizer when heated past 400 F to trigger the hydrogen and Lithium in the Pe.

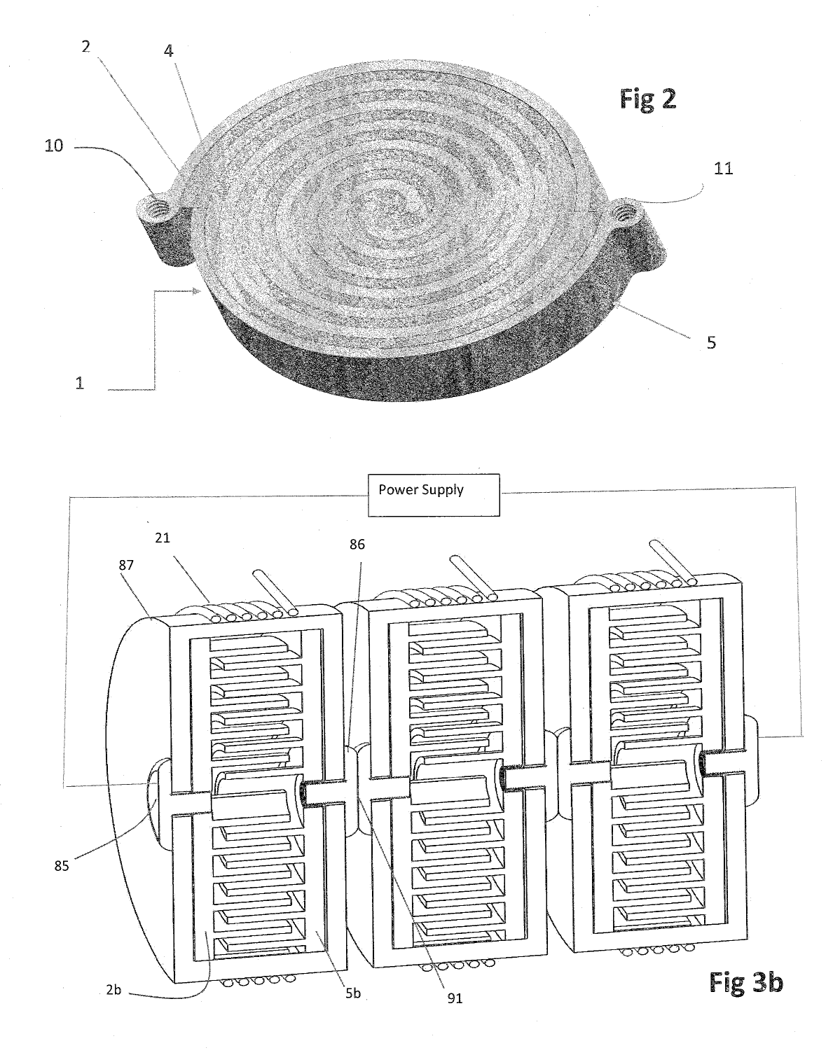

FIG. 3a shows a non-inductive cell that includes two electrical opposing electrodes 2b and 5b with alignment notches 84 and 83 to prevent shorting. The injection molded fuel is not shown, but can be seen in FIG. 2 as element 4. The electrical schematic can be found in FIG. 1a. The difference between FIG. 1 and FIG. 3a is that, in FIG. 1, a switching AC power supply creates a switching magnetic and inductive field from the coiled isolated electrodes, while in FIG. 3a, the electrodes are machined or formed as solid electrodes that prevent a magnetic inductive field. It has been shown in U.S. Pat. No. 8,419,919 that permeate magnetics with a magnetic field is beneficial in an exothermic surface reaction. The present invention varies the arrangement disclosed in U.S. Pat. No. 8,419,919 by, instead of using heavy water (deuterium) that costs $1,000 per gallon, the present invention uses a polymer and Ni or Fe, with the polymer being reclaimed at landfills at a very low cost, eliminating the need for expensive precious metals, although such metals could be used with another feature of the invention, which is also different from U.S. Pat. No. 8,419,919, namely that the electrodes in a lithium, polyethylene, nickel, or iron matrix have a switching magnetic field with or without a polarity reversal rather than the DC currents used in U.S. Pat. No. 8,419,919 to maintain a constant current between the non-inductive electrodes, so that the current never changes directions within the electrodes. Furthermore, the present invention uses a solid, safe polymer fuel rather than a liquid or exploding gas fuel stored in a pressurized storage tank, or pure lithium which requires special precautions with additional cost to transport and store safely. In addition, U.S. Pat. No. 8,419,919 doesn't use a feedback loop to maintain the osculations within the lattice, nor does it use a plasma to amplify the exothermic surface reaction and temperatures of the reactor cell to improve the efficiencies of the Enhanced Exothermic Reactions (EERs).

The electrical circuit in FIG. 1f represents the invention in FIGS. 3b, 2, 6, 4, 3, 11, 5, and 9. None of the cited patents or pending applications address the problem of spent fuels and unusable metals once they are transmuted into an unusable metal electrode. The present invention can provide both the lithium, polyethylene and nickel with iron and other materials as an extruded filament or injection molded form to replace the spent fuels with an auger or other methods on the fly, with the additional benefit of turning the carbon from the polymer fuel into a usable graphene that is a benefit that no prior EER reactor possesses, the graphene being manufactured from the waste carbon to produce electrical wire, carbon nanotubes and graphene flakes.

In addition to an auger, a piston pump or gas pressure can be used to transport the spent fuel out of the reactor heated zone. For example a linear motorized solid tube ceramic plunger can clear the heater tube 65 in FIG. 16 and recoil back to pump the new fuel from hopper 37 back into the heater zone through the opening 66 without an auger. The plunger can be driven by a linear sliding stepper or gear motor (not shown). The cross-linked graphene is intertwined with the nickel powder to produce a highly conductive wire. The ionized hydrogen gas will produce the plasma. The resistance of the polymer can be tailored by the amount of conductive materials used such as graphene flakes, carbon nanotubes, and nickel powders with iron powders, and the voltage applied across the electrodes can be used to tailor and control the reaction temperature. The rollers 96,97 in FIG. 23 pull the extrusion graphene to form a filament graphene conductive wire and align the crystals in the melted metal Ni and other metals to control the alignment of the cross-linked graphene. Oxygen and heat can be added to the graphene outside of the Enhanced Exothermic Reactions (EERs) to cause oxidation within the graphene if desirable.

I claim:

1. A reactor for producing enhanced exothermic reactions (EER) by pressurized hydrogen loading of metals with lithium, comprising:
a pair electrodes supplied with an electric current, one of said electrodes including a transition metal into which hydrogen is loaded;
a hydrogen source for supplying hydrogen to said one of the electrodes, said hydrogen being in the form of a hydrogen-containing polymer fuel;
a heater for heating the hydrogen-containing polymer fuel to ionize the hydrogen and generate a hydrogen plasma that facilitates the hydrogen loading, the hydrogen loading causing an enhanced exothermic reaction that generates heat.

2. A reactor as claimed in claim 1, further comprising a turbine or thermo-electric generator for converting heat generated by the enhanced exothermic reaction into electricity.

3. A reactor as claimed in claim 1, wherein the polymer fuel is a lithium-polymer with transition metal powders that contains hydrogen or deuterium.

4. A reactor as claimed in claim 3, wherein the transition metal powders include nickel, titanium, iron, or steel and the polymer fuel is in liquid, powder, filament, or pellet form, and further comprising a feeder mechanism for transporting the polymer mixed fuels into a space between the electrodes and for removing spent fuel from between the electrodes.

5. A reactor as claimed in claim 4, wherein the feeder mechanism is a motor-driven plastic injection molding auger extending within a feeder tube with an electronic temperature controlled feedback loop

6. A reactor as claimed in claim 5, wherein the feeder tube is surrounded by a heat exchanger to extract heat from enhanced exothermic reactions that occur within the tube.

7. A reactor as claimed in claim 5, wherein the auger forms one of the pair of electrodes and is charged to create a heat reaction between the second of the pair of electrodes.

8. A reactor as claimed in claim 4, wherein the feeder mechanism is a motorized intermittent feeder mechanism with a feedback loop that is electrically resistive load or temperature dependent to control the feed rate speed of fuel to the reactor, and wherein the feedback loop measures a temperature of the reactor or a resistance of the electrical current driven through the fuel to determine the feed rate speed of the auger.

9. A reactor as claimed in claim 3, wherein the polymer fuel is heated to release hydrogen gas to said one of the electrodes as the polymer fuel is transported to the space between the electrodes.

10. A reactor as claimed in claim 3, wherein the heated lithium polymer and transition metal powder fuel forms a cross-linked graphene that is shaped by an extrusion nozzle upon exiting the reactor as spent fuel.

11. A reactor as claimed in claim 1, wherein:
one of the electrodes plated with a hydrogen soaking transition metal,
a dielectric and/or resistive material situated between the electrodes,
wherein the electric current is an AC or switching DC current supplied by a current source and applied to the electrodes to cause an ionizing current to flow in the dielectric and/or resistive material and cause release of hydrogen to the hydrogen soaking transition metal to form a battery or capacitor to store an electrical charge.

12. A reactor as claimed in claim 11, further comprising a pick-up coil surrounding the dielectric or resistive material, wherein currents or arcing in said dielectric or resistive material induce currents in said pick-up coil, the currents induced in said pick-up coil being supplied to a load and/or supplied as a feedback signal to control said supply of hydrogen.

13. A reactor as claimed in 12, wherein said electrodes form a capacitor or inductor, and further comprising a resistor connected to the electrodes to form an RC or RLC circuit, said RC or RLC circuit varying said currents in said dielectric or resistive material based on the degree of hydrogen loading by the hydrogen plasma or polymer fuel and the heat generated by the enhance exothermic reactions.

14. A reactor as claimed in claim 1, wherein the electrodes are intertwined helical electrodes, said electrodes being made of a magnetically inductive material such that the power supply creates switching magnetic fields between the electrodes.

15. An electrochemical cell for producing enhanced exothermic reactions (EER) by pressurized hydrogen loading of metals, comprising:
a pair electrodes;
a source of hydrogen;
a mechanism for transporting the hydrogen into a space between the electrodes, wherein:
one of the electrodes plated with a hydrogen soaking transition metal,
a dielectric and/or resistive material is situated between the electrodes,
wherein the electric current is an AC or switching DC current supplied by a current source and applied to the electrodes to cause an ionizing current to flow in the dielectric and/or resistive material and cause release of hydrogen to the hydrogen soaking transition metal.

16. A reactor as claimed in claim 15, further comprising a pick-up coil surrounding the dielectric or resistive material, wherein currents or arcing in said dielectric or resistive material induce currents in said pick-up coil, the currents induced in said pick-up coil being supplied to a load and/or supplied as a feedback signal to control said supply of hydrogen.

17. A reactor as claimed in 16, wherein said electrodes form a capacitor or inductor, and further comprising a resistor connected to the electrodes to form an RC or RLC circuit, said RC or RLC circuit varying said currents in said dielectric or resistive material based on the degree of hydrogen loading by the hydrogen plasma or polymer fuel and the heat generated by the enhance exothermic reactions.

18. A reactor as claimed in claim 15, wherein the electrodes are intertwined helical electrodes, said electrodes being made of a magnetically inductive material such that the power supply creates switching magnetic fields between the electrodes.

19. A reactor as claimed in claim 15, wherein the polymer fuel is a lithium polymer having capacitive and resistive properties and the electric current applied to the electrodes is a switching current that causes counter-electromotive forces from stored inductive or capacitive loads between the electrodes to periodically reverse, the resulting switching magnetic field thereby causing harmonic oscillations within a lattice of the transition metal and cause the lattice to pack the hydrogen and assist in a ferromagnetic spin and femtometer-level EER that occurs in isotopes with low lying excited states.

20. An EER plasma reactor with a filament feed for supplying fuel into the EER plasma reactor, comprising:
rollers for feeding the filament into a porous ceramic membrane;
electrodes at each end of the membrane;
an RF power supply for supplying an RF current that is carried between the electrodes and heats a conductive polymer fuel feed stock to produce a hydrogen gas that escapes through the ceramic membrane and produces a plasma in a plasma chamber to add additional heat to the EER reactor.

21. A plasma discharge heat source, comprising:
a microwave power supply; and
an antenna,
wherein coupled microwaves vibrate and heat a metal lattice to produce a microwave reaction that is picked up by an antenna and fed back into the microwave power supply for a complete closed feedback loop that keeps the metal lattice vibration in constant resonance natural vibration oscillations.
